(19) United States
(12) Patent Application Publication
(10) Pub. No.: US 2026/0052893 A1
(43) Pub. Date: Feb. 19, 2026

(54) DISPLAY DEVICE AND ELECTRONIC DEVICE INCLUDING THE SAME

(71) Applicant: Samsung Display Co., Ltd., Yongin-Si (KR)

(72) Inventor: Moon Chul PARK, Yongin-si (KR)

(21) Appl. No.: 19/095,029

(22) Filed: Mar. 31, 2025

(30) Foreign Application Priority Data
Aug. 13, 2024 (KR) 10-2024-0108258

(51) Int. Cl. H10K 59/80; H05K 7/20; H10K 59/95

(52) U.S. Cl. CPC H10K 59/8794; H05K 7/20963; H10K 59/95

(57) ABSTRACT

A display device includes a display panel, a panel bottom member disposed under the display panel, a driver circuit board connected to the display panel, a control circuit board connected to the driver circuit board, and a heat dissipation member disposed in at least one of the panel bottom member, the driver circuit board, or the control circuit board.

### CROSS-REFERENCE TO RELATED APPLICATION

This application claims priority to Korean Patent Application No. 10-2024-0108258 filed on Aug. 13, 2024, in the Korean Intellectual Property Office, and all the benefits accruing therefrom under 35 U.S. C. 119, the contents of which in its entirety are herein incorporated by reference.

### BACKGROUND

### 1. Field of the Disclosure

The present disclosure relates to a display device and an electronic device including the same.

### 2. Description of the Related Art

Electronic devices such as a smart phone, a tablet PC, a digital camera, a laptop computer, a navigation device and a smart TV include a display device for displaying images.

A display device may include a plurality of light-emitting elements. The plurality of light-emitting elements may display images through power applied from an external source. Some of the power applied to the light-emitting elements may not be converted into light energy but may be accumulated in the display device in the form of heat energy. The heat accumulated in the display device is one of the main causes of deterioration of the display quality of the display device.

As display devices become more advanced and compact, the electronic components inside the display devices also become more highly integrated, and accordingly the heat density increases. Under the circumstances, a need for a technology that may more effectively dissipate the generated heat has emerged.

### SUMMARY

The present disclosure provides a display device capable of effectively dissipating heat generated from internal electronic components of a display device, and an electronic device including the same.

However, features of the present disclosure are not restricted to those set forth herein. The above and other features of the present disclosure will become more apparent to one of ordinary skilled in the art to which the present disclosure pertains with reference to the detailed description of the present disclosure.

According to an embodiment of the present disclosure, a display device includes a display panel, a panel bottom member disposed under the display panel, a driver circuit board connected to the display panel, a control circuit board connected to the driver circuit board, and a heat dissipation member disposed in at least one of the panel bottom member, the driver circuit board, or the control circuit board.

The display device may further include a driver integrated circuit disposed under the panel bottom member, and the heat dissipation member may be disposed in the panel bottom member and overlap with the driver integrated circuit.

A top plate of the heat dissipation member may be in contact with the display panel, and a bottom plate of the heat dissipation member may be in contact with the driver integrated circuit.

The display device may further include a cable connecting the driver circuit board with the control circuit board, and the heat dissipation member may be disposed in the driver circuit board and overlap with the cable.

A top plate of the heat dissipation member may be in contact with the panel bottom member, and a bottom plate of the heat dissipation member may be in contact with the cable.

The display device may further include a cable connecting the driver circuit board with the control circuit board, and the heat dissipation member may be disposed in the control circuit board and overlap with the cable.

A top plate of the heat dissipation member may be in contact with the cable.

The heat dissipation member may include a top plate, a bottom plate spaced apart from the top plate, and a plurality of heat dissipation fins connecting the top plate with the bottom plate.

A first side of each of the plurality of heat dissipation fins may be in contact with the top plate, and a second side of each of the plurality of heat dissipation fins may be in contact with the bottom plate., Each of the plurality of heat dissipation fins may include a heat dissipation hole that extends through each of the plurality of heat dissipation fins from the first side to the second side.

The display panel may include a substrate, and a plurality of light-emitting elements disposed on a surface of the substrate. The substrate may include a power supply line supplying power to the plurality of light-emitting elements, a plurality of heat dissipation terminals overlapping the power supply line, a plurality of heat dissipation lines connecting each of the plurality of heat dissipation terminals, and a heat dissipation pad disposed on the surface of the substrate and connected to the plurality of heat dissipation lines.

The power supply line may extend from an area adjacent to the plurality of light-emitting elements to an area adjacent to the heat dissipation pad. The plurality of heat dissipation terminals may include a first heat dissipation terminal, a second heat dissipation terminal, a third heat dissipation terminal and a fourth heat dissipation terminal. The first heat dissipation terminal and the second heat dissipation terminal may be spaced apart from each other in a first direction and overlap with the power supply line disposed in the area adjacent to the light-emitting element, and the third heat dissipation terminal and the fourth heat dissipation terminal may be spaced apart from each other in the first direction and overlap with the power supply line disposed in the area adjacent to the heat dissipation pad.

The plurality of heat dissipation lines may include a first heat dissipation line and a second heat dissipation line. The first heat dissipation line extending in the first direction may connect the first heat dissipation terminal with the second heat dissipation terminal, and connect the third heat dissipation terminal with the fourth heat dissipation terminal. The second heat dissipation line extending in a second direction intersecting the first direction may connect the first heat dissipation line with the heat dissipation pad.

According to an embodiment of the present disclosure, an electronic device includes a display panel, a panel bottom member disposed under the display panel, a driver circuit board connected to the display panel, a bracket disposed under of the driver circuit board, a control circuit board connected to the driver circuit board and disposed under the bracket, and a plurality of heat dissipation members disposed in at least one of the panel bottom member, the driver circuit board, the bracket, or the control circuit board.

The electronic device may further include a driver integrated circuit disposed under the panel bottom member. The plurality of heat dissipation members may include a first heat dissipation member and a second heat dissipation member, and the first heat dissipation member and the second heat dissipation member may be disposed in the panel bottom member and overlap with the driver integrated circuit.

A top plate of each of the first heat dissipation member and the second heat dissipation member may be in contact with the display panel, and a bottom plate of each of the first heat dissipation member and the second heat dissipation member may be in contact with the driver integrated circuit.

The electronic device may further include a cable connecting the driver circuit board with the control circuit board. The plurality of heat dissipation members may include a third heat dissipation member and a fourth heat dissipation member. The third heat dissipation member may be disposed in the driver circuit board and overlap with the cable, and the fourth heat dissipation member may be disposed in the control circuit board and overlap with the cable.

A top plate of the third heat dissipation member may be in contact with the panel bottom member, and a bottom plate of the third heat dissipation member may be in contact with the cable. A bottom plate of the fourth heat dissipation member may be in contact with the cable, and a top plate of the fourth heat dissipation member may be in contact with the bracket.

The plurality of heat dissipation members may further include a fifth heat dissipation member and a sixth heat dissipation member. The fifth heat dissipation member may be disposed in the bracket and overlap with the first heat dissipation member, and the sixth heat dissipation member may be disposed in the bracket and overlap with the second heat dissipation member.

The plurality of heat dissipation members may further include a seventh heat dissipation member, and the seventh heat dissipation member may be disposed in the bracket and overlap with the driver circuit board.

The electronic device may further include a connecting member connecting the display panel with the driver circuit board, a cable connecting the driver circuit board with the control circuit board, and a vapor chamber disposed under the bracket. A top plate of each of the fifth heat dissipation member and the sixth heat dissipation member may be in contact with the connecting member, and a bottom plate of each of the fifth heat dissipation member and the sixth heat dissipation member may be in contact with the vapor chamber. A top plate of the seventh heat dissipation member may be in contact with the cable, and a bottom plate of the seventh heat dissipation member may be in contact with the vapor chamber.

According to an embodiment of the present disclosure, by placing a plurality of heat dissipation members in a bracket supporting the internal electronic components of a display device and the display device, it is possible to effectively dissipate heat generated in the internal electronic components of the display device to the outside of the display device.

The effects of the present disclosure are not limited to those described above and other effects of the present disclosure will be apparent to those skilled in the art from the following descriptions.

### BRIEF DESCRIPTION OF THE DRAWINGS

The above and other features of the present disclosure will become more apparent by describing in detail the embodiment of the present disclosure with reference to the attached drawings.

FIG. 1 is a plan view showing an electronic device according to an embodiment of the present disclosure.

FIG. 2 is a plan view showing a bent state of a connecting member of a display device according to an embodiment of the present disclosure.

FIG. 3 is a plan view showing an unfolded state of a connecting member of a display device according to an embodiment of the present disclosure.

FIG. 4 is a cross-sectional view taken along a line B-B′ of FIG. 2.

FIG. 5 is a cross-sectional view showing a display panel shown in FIG. 4.

FIG. 6 is a perspective view showing a heat dissipation member shown in FIG. 4.

FIG. 7 is an exploded perspective view of a heat dissipation member shown in FIG. 6.

FIG. 8 is a side view of a heat dissipation member shown in FIG. 6.

FIG. 9 is a plan view showing a part of a substrate shown in FIG. 4.

FIG. 10 is a plan view showing a connected state of a plurality of heat dissipation terminals, a plurality of heat dissipation lines, and a plurality of heat dissipation pads arranged on a part of a substrate shown in FIG. 9.

FIG. 11 is a plan view showing an arrangement of a plurality of heat dissipation terminals, a plurality of heat dissipation lines and a plurality of heat dissipation pads on a part of a substrate shown in FIG. 9.

FIG. 12 is a cross-sectional view taken along a line A-A′ of FIG. 1.

### DETAILED DESCRIPTION OF THE EMBODIMENTS

Advantages and features of the present disclosure and methods to achieve them will become apparent from the descriptions of embodiments hereinbelow with reference to the accompanying drawings. However, the present disclosure is not limited to the embodiments disclosed herein but may be implemented in various different ways. These embodiments are merely provided to ensure the full disclosure of the present inventive concept and to completely convey the scope of the present disclosure to those skilled in the art. It is to be noted that the scope of the present disclosure is defined only by the claims.

As used herein, a phrase, “an element A on an element B,” refers to not only a situation where the element A is disposed directly on the element B but also a situation where the element A is disposed indirectly on the element B via another element C. Like reference numerals denote like elements throughout the descriptions. The figures, dimensions, ratios, angles, numbers of elements given in the drawings are merely illustrative and are not limiting.

Although the terms “first”, “second”, etc. may be used herein to describe various elements, these elements should not be limited by these terms. These terms may be used to distinguish one element from another element. Thus, a first element discussed below may be termed a second element without departing from the teachings of the present disclosure.

Each of the features of the various embodiments of the present disclosure may be partially or entirely combined with each other and technically interwork with each other in various ways. Each embodiment may be implemented independently from each other or may be implemented together in association with each other.

Hereinafter, embodiments of the present disclosure will be described in detail with reference to the accompanying drawings.

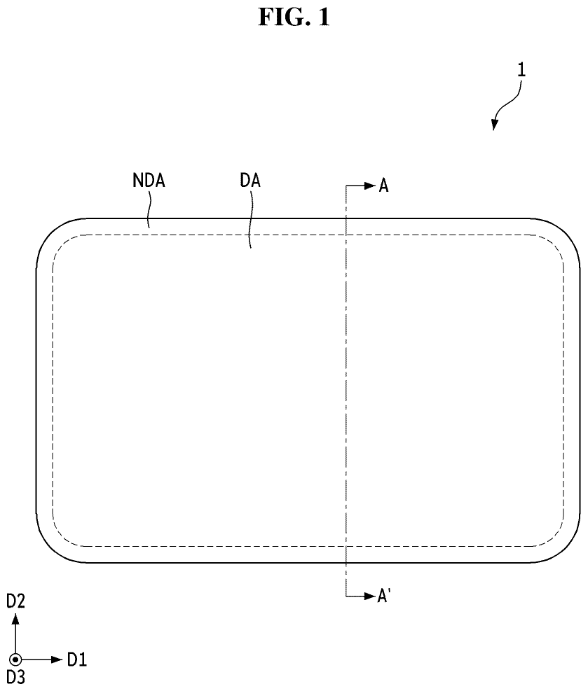

FIG. 1 is a plan view showing an electronic device according to an embodiment of the present disclosure.

The first direction D1 of FIG. 1 may refer to a direction parallel to a first side of the electronic device 1, for example, a horizontal direction of the electronic device 1 when viewed from the top. The second direction D2 may refer to a direction parallel to a second side of the electronic device 1 that meets the first side of the electronic device 1, for example, a vertical direction of the electronic device 1 when viewed from the top. In the following description, one side in the first direction DR1 may indicate a right side of the electronic device 1 when viewed from the top, and the opposite side in the first direction DR1 may indicate a left side of the electronic device 1 when viewed from the top. In addition, one side in the second direction DR2 may indicate an upper side of the electronic device 1 when viewed from the top, and the opposite side in the second direction DR2 may indicate a lower side of the electronic device 1 when viewed from the top, for convenience of illustration. A third direction D3 may refer to a thickness direction of the electronic device 1. However, it should be understood that the directions referred to in the embodiment are relative directions, and the embodiment are not limited to the directions mentioned above.

In this embodiment, the terms “top” and “upper surface” in the third direction D3 may refer to a display side, through which images are displayed, of the display device 10, while the terms “bottom” and “lower surface” in the third direction D3 may refer to an opposite side of the display device 10 in the third direction D3.

According to an embodiment of the present disclosure, the electronic device 1 may include a variety of electronic devices that display images. Examples of the electronic device 1 may include, but are not limited to, a mobile phone, a smart phone, a tablet PC, a mobile communications terminal, an electronic organizer, an e-book, a personal digital assistant (PDA), a portable multimedia player (PMP), a navigation device, an ultra mobile PC (UMPC), a television set, a game machine, a wristwatch-type electronic device, a head-mounted display, a personal computer monitor, a laptop computer, a vehicle instrument cluster, a digital camera, a camcorder, an outdoor billboard, an electronic billboard, various medical apparatuses, various inspection devices, various home appliances including a display area such as a refrigerator or a laundry machine, Internet of things (IoT) devices, etc. Examples of the electronic device 1 to be described later may further include, but are not limited to, a smartphone, a tablet PC, a laptop computer, etc.

Referring to FIG. 1, the electronic device 1 may include a display area DA and a non-display area NDA. The shape of the display area DA may be substantially the same as or similar to the shape of the electronic device 1 when viewed from the top. For example, when the electronic device 1 has a rectangular shape when viewed from the top, the display area DA may also have a rectangular shape when viewed from the top.

The display area DA may include a plurality of pixels which display images. The non-display area NDA may not display image because the non-display area NDA does not include the pixels. The non-display area NDA may be disposed around the display area DA. The non-display area NDA may surround the display area DA, but the embodiments of the present disclosure are not limited thereto. For example, the display area DA may be partially surrounded by the non-display area NDA.

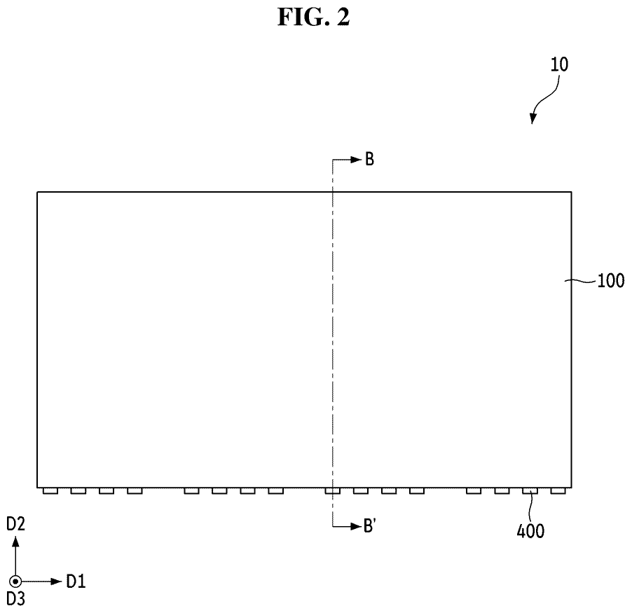

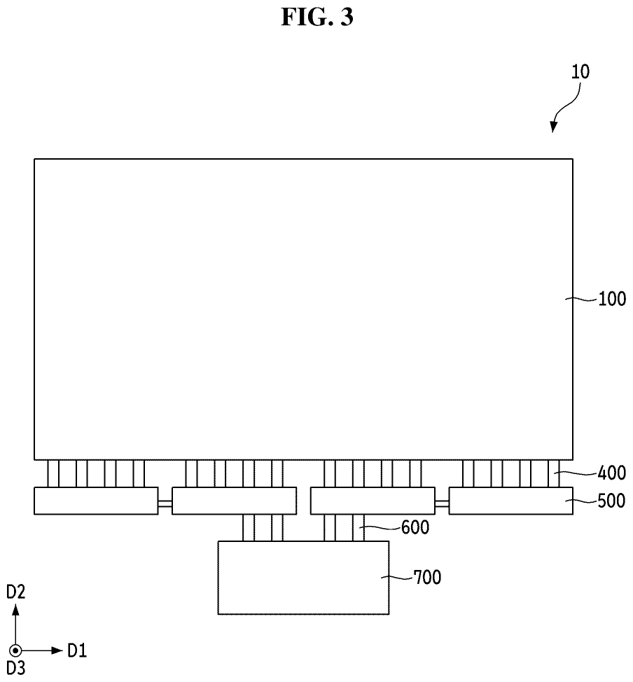

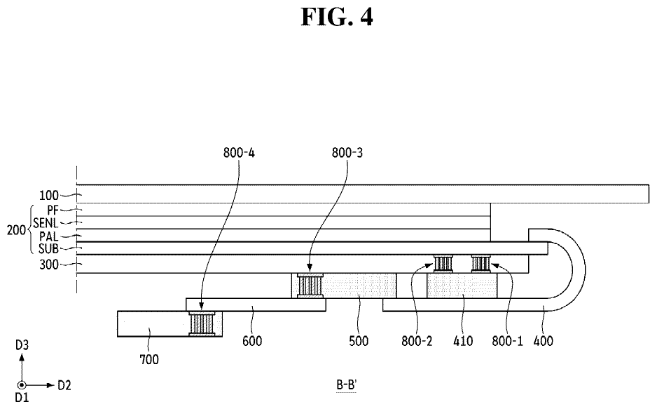

FIG. 2 is a plan view showing a bent state of a connecting member of a display device according to an embodiment of the present disclosure. FIG. 3 is a plan view showing an unfolded state of the connecting member of the display device according to an embodiment of the present disclosure. FIG. 4 is a cross-sectional view taken along line a B-B′ of FIG. 2.

The electronic device 1 according to an embodiment may include the display device 10. The display device 10 may be a light-emitting display device such as an organic light-emitting display device using organic light-emitting diodes, a quantum-dot light-emitting display device including quantum-dot light-emitting layer, an inorganic light-emitting display device including an inorganic semiconductor, or a micro light-emitting display device using micro light-emitting diodes (LED). In the following description, an organic light-emitting display device is described as an example of the display device 10. It is, however, to be understood that the present disclosure is not limited thereto.

The display device 10 may have a quadrangular shape, such as a rectangular shape when viewed from the top. For example, the display device 10 may have a rectangular shape having longer sides in the first direction D1 and shorter sides in the second direction D2 when viewed from the top. The corners where the longer sides in the first direction D1 meet the shorter sides in the second direction D2 may be rounded with a predetermined curvature or may be a right angle. The shape of the display device 10 when viewed from the top is not limited to a rectangular shape but may be formed in another shape such as a polygonal shape, a circular shape, or an elliptical shape.

Referring to FIGS. 2 to 4, the display device 10 may include a cover window 100, a display panel 200, a panel bottom member 300, a connecting member 400, a driver circuit board 500, a cable 600, a control circuit board 700, and a heat dissipation member 800.

The cover window 100 may include a material with high light transmittance. The cover window 100 may include a polymer resin such as polyimide or glass. The cover window 100 may be attached onto a polarizing film PF of the display panel 200 by an adhesive member such as an optically clear adhesive (OCA) film.

The display panel 200 may be disposed under the cover window 100. The display panel 200 may have a rectangular shape having longer sides in the first direction D1 and shorter sides in the second direction D2 when viewed from the top. In the display panel 200, the corners where the longer sides in the first direction D1 meet the shorter sides in the second direction D2 may be formed at a right angle or may be rounded with a predetermined curvature. However, the present disclosure is not limited thereto. For example, the display panel 200 may have a quadrangular shape, a polygonal shape other, a circular shape, an oval shape, or an irregular shape when viewed from the top.

The display panel 200 may include a display area DA where emission areas which emit light are located, and a non-display area NDA around the display area DA. The non-display area NDA may surround the display area DA. A plurality of display pads may be disposed in the non-display area NDA, for example, at one edge of the display panel 200.

The display panel 200 may include a substrate SUB, a display unit PAL, a sensor unit SENL and a polarizing film PF.

The substrate SUB may include an insulating material such as glass, quartz or a polymer resin. The substrate SUB may be a rigid substrate or a flexible substrate that can be bent, folded, rolled, and so on.

The display unit PAL may be disposed on the substrate SUB. The display unit PAL may include a plurality of layers and include a plurality of emission areas that emit light. The display unit PAL may include a buffer film, a thin-film transistor layer on which thin-film transistors are disposed, a light-emitting element layer that emits light, and an encapsulating layer for encapsulating the light-emitting element layer.

The sensor unit SENL may be disposed on the display unit PAL. The sensor unit SENL may include sensor electrodes and may sense whether there is a user's touch.

The polarizing film PF may be disposed on the sensor unit SENL. The polarizing film PF can prevent the deterioration of image visibility of the display panel 200 due to reflection of external light. The polarizing film may include a linear polarizer and a retardation film such as a λ/4 (quarter-wave) plate. The phase retardation film may be disposed on the sensor unit SENL, and the linear polarizer may be disposed on the phase retardation film. The cover window 100 may be disposed on the polarizing film PF.

The panel bottom member 300 may be disposed under the substrate SUB. The panel bottom member 300 may be attached to a lower surface of the substrate SUB by an adhesive member. The adhesive member may be a pressure-sensitive adhesive (PSA). The panel bottom member 300 may include at least one of a light-absorbing member for absorbing light incident from outside, a buffer member for absorbing external impact, or a heat dissipating member for efficiently discharging heat from the display panel 200.

The light-absorbing member may be disposed under the substrate SUB. The light-absorbing member blocks the transmission of light to prevent the elements disposed thereunder, such as the driver circuit board 500, from being visible from the top of the display panel 200. The light-absorbing member may include a light-absorbing material such as a black pigment or a black dye.

The buffer member may be disposed under the light-absorbing member. The buffer member absorbs an external impact to prevent the display panel 200 from being damaged. The buffer member may include a single layer or multiple layers. For example, the buffer member may include a polymer resin such as polyurethane, polycarbonate, polypropylene or polyethylene, or may include a material having elasticity such as a rubber or a sponge obtained from a urethane-based material or an acrylic-based material.

The heat dissipating member may be disposed under the buffer member. The heat dissipation member may include a first heat dissipation layer including graphite or carbon nanotubes, and a second heat dissipation layer including a thin metal film such as copper, nickel, ferrite or silver, which can block electromagnetic waves and have high thermal conductivity.

The connecting member 400 may be connected to a plurality of display pads of the display panel 200 through a conductive adhesive member such as an anisotropic conductive film. Accordingly, the display panel 200 and the connecting member 400 may be electrically connected with each other.

In addition, the connecting member 400 may be connected to a plurality of circuit pads of the driver circuit board 500 through a conductive adhesive member such as an anisotropic conductive film. As a result, the connecting member 400 and the driver circuit board 500 may be electrically connected with each other.

The connecting member 400 may be a flexible printed circuit board or a chip-on film.

A driver integrated circuit 410 may be disposed on a surface of the connecting member 400. The driver integrated circuit 410 may generate data voltages, supply voltages, scan timing signals, etc., and output them to the display panel 200. The driver integrated circuit 410 may be disposed on, but is not limited to, a surface of the connecting member 400. For example, the driver integrated circuit 410 may be disposed between a plurality of display pads and the display area DA in the non-display area NDA of the display panel 200.

The driver circuit board 500 may be placed under the panel bottom member 300 when the connecting member 400 is bent. The driver circuit board 500 may be a flexible printed circuit board (FPCB) that can be bent, a rigid printed circuit board (PCB), or a composite printed circuit board including both a rigid printed circuit board and a flexible printed circuit board.

The driver circuit board 500 may process the signal converted by the control circuit board 700 and transmit the signal to the display panel 200. The driver circuit board 500 may be electrically connected to the display panel 200 through the connecting member 400.

The cable 600 may connect the driver circuit board 500 with the control circuit board 700. The cable 600 may connect the driver circuit board 500 with the control circuit board 700 through connectors each of which is disposed on one surface of either the driver circuit board 500 or the control circuit board 700.

Connection terminals (not shown) may be disposed on both ends of the cable 600. When the cable 600 is connected to the connectors, the connection terminals of the cable 600 may be connected to connection pins of the connectors. In this way, the cable 600 connecting the driver circuit board 500 with the control circuit board 700 may provide a path for a signal converted in the control circuit board 700 to be transmitted to the driver circuit board 500.

The control circuit board 700 may be connected to the driver circuit board 500 and may be located under the panel bottom member 300 when the connecting member 400 is bent. The control circuit board 700 may be a flexible printed circuit board (FPCB), a rigid printed circuit board (PCB), or a composite printed circuit board including both a rigid printed circuit board and a flexible printed circuit board.

The control circuit board 700 may convert a signal for displaying images and a signal for power provided from a system into signals to be provided to the display panel 200. The control circuit board 700 may include an integrated circuit chip that converts a signal provided from the system. The control circuit board 700 may be electrically connected to the driver circuit board 500 through the cable 600.

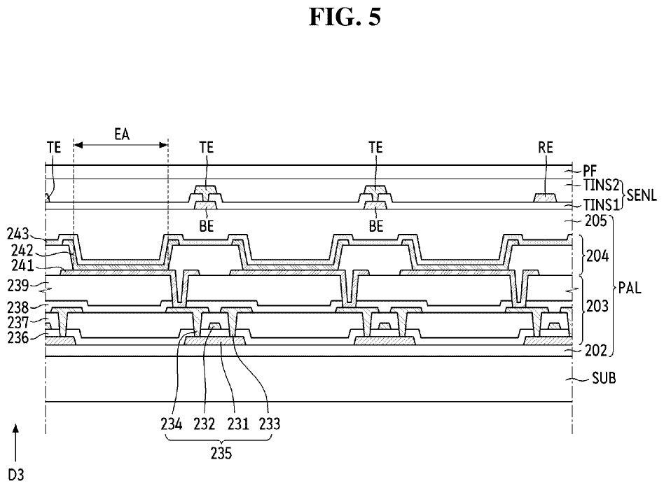

FIG. 5 is a cross-sectional view showing the display panel shown in FIG. 4.

Referring to FIG. 5, the display unit PAL may include a buffer film 202, a thin-film transistor layer 203, a light-emitting element layer 204, and an encapsulation layer 205.

The buffer film 202 may be disposed on the substrate SUB. The buffer film 202 may protect the thin-film transistors 235 and the light-emitting element layer 204 from moisture permeating through the substrate SUB. The buffer layer 202 may include a plurality of inorganic layers stacked on one another alternately. For example, the buffer layer 202 may include multiple layers in which one or more inorganic layer of a silicon oxide layer (SiOx), a silicon nitride layer (SiNx) and SiON are stacked on one another alternately. The buffer film 202 may be eliminated.

The thin-film transistor layer 202 is disposed on the buffer layer 203. The thin-film transistor layer 203 includes thin-film transistors 235, a gate insulator 236, an interlayer dielectric film 237, a protective film 238, and an organic film 239.

Each of the thin-film transistor 235 includes an activate layer 231, a gate electrode 232, a source electrode 233, and a drain electrode 234. In FIG. 5, the thin-film transistors 235 are implemented as top-gate transistors in which the gate electrode 232 is located above the active layer 231. It is, however, to be understood that the present disclosure is not limited thereto. That is to say, the thin-film transistors 235 may be implemented as bottom-gate transistors in which the gate electrode 232 is located below the active layer 231, or as double-gate transistors in which the gate electrodes 232 are disposed above and below the active layer 231.

The active layer 231 is disposed on the buffer layer 202. The active layer 231 may include a silicon-based semiconductor material or an oxide-based semiconductor material. For example, the active layer 231 may include a polycrystalline silicon, an amorphous silicon, or an oxide semiconductor. A light-blocking layer for blocking external light incident on the active layer 231 may be formed between the buffer layer 202 and the active layer 231.

The gate insulator 236 may be disposed on the active layer 231. The gate insulator 236 may include an inorganic layer, for example, a silicon oxide layer (SiOx), a silicon nitride layer (SiNx), or a multilayer thereof.

The gate electrodes 232 may be disposed on the gate insulator 236. The gate electrodes 232 and the gate lines may include a single layer or multiple layers of one of molybdenum (Mo), aluminum (Al), chromium (Cr), gold (Au), titanium (Ti), nickel (Ni), neodymium (Nd), copper (Cu) or an alloy thereof.

The interlayer dielectric film 237 may be disposed on the gate electrodes 232 and the gate lines. The interlayer dielectric film 237 may include an inorganic layer, for example, a silicon oxide layer (SiOx), a silicon nitride layer (SiNx), or a multilayer thereof.

The source electrodes 233 and the drain electrodes 234 may be disposed on the interlayer dielectric film 237. Each of the source electrodes 233 and the drain electrodes 234 may be connected to the active layer 231 through a contact hole penetrating through the gate insulator 236 and the interlayer dielectric film 237. The source electrode 233 and the drain electrode 234 may include a single layer or multiple layers of one of molybdenum (Mo), aluminum (Al), chromium (Cr), gold (Au), titanium (Ti), nickel (Ni), neodymium (Nd), copper (Cu) or an alloy thereof.

The protective film 238 may be disposed on the source electrode 233 and the drain electrode 234 in order to insulate the thin-film transistors 235. The protective film 238 may include an inorganic layer, e.g., a silicon oxide layer (SiOx), a silicon nitride layer (SiNx), or a multilayer thereof.

The organic film 239 may be disposed on the protective film 238 to provide a flat surface over the thin-film transistors 335 having difference levels. The organic film 239 may be implemented as an organic layer such as an acryl resin, an epoxy resin, a phenolic resin, a polyamide resin or a polyimide resin.

The light-emitting element layer 204 is disposed on the thin-film transistor layer 203. The light-emitting element layer 204 includes the light-emitting elements and a bank.

The light-emitting elements and the bank are disposed on the organic film 239. The light-emitting elements may include an anode electrode 241, an emissive layer 242 and a cathode electrode 243, which are typical components of an organic light-emitting device.

The anode electrode 241 may be disposed on the organic film 239. The anode electrode 241 may be connected to the source electrode 233 of the thin-film transistor 235 via a contact hole penetrating through the protective film 238 and the organic film 239.

The bank may be disposed on the organic film 239 and cover an edge of the anode electrode 241 to define an emission areas EA of the pixels. That is to say, the bank may define the emission areas EA of the pixels. In each of the pixels, the anode electrode 241, the emissive layer 242 and the cathode electrode 243 are sequentially stacked on one another so that holes from the anode electrode 241 and electrons from the cathode electrode 243 combine in the emissive layer 242 to emit light.

The emissive layer 242 is disposed on the anode electrode 241 and the bank. The emissive layer 242 may be an organic emissive layer. The emissive layer 242 may emit one of red light, green light, and blue light. The emissive layer 242 may be a white emissive layer that emits white light. In such case, the red emissive layer, the green emissive layer and the blue emissive layer may be stacked on one another, or the white emissive layer may be formed commonly across the pixels as a common layer. In such case, the display panel 200 may further include additional color filters for representing red, green and blue colors.

The emissive layer 242 may include a hole transporting layer, a light-emitting layer, and an electron transporting layer. In addition, the emissive layer 242 may be formed in a tandem structure of two or more stacks, in which case a charge generating layer may be formed between the stacks.

The cathode electrode 243 is disposed on the emissive layer 242. The cathode electrode 243 may be formed to cover the emissive layer 242. The cathode electrode 243 may be a common layer formed across the pixels.

When the light-emitting element layer 204 is of a top-emission type in which light exits toward the upper side, the anode electrode 241 may include a metal material having a high reflectivity such as a stack structure of aluminum and titanium (Ti/Al/Ti), a stack structure of aluminum and ITO (ITO/Al/ITO), an APC alloy or a stack structure of APC alloy and ITO (ITO/APC/ITO). The APC alloy is an alloy of silver (Ag), palladium (Pd) and copper (Cu). The cathode electrode 243 may include a transparent conductive material (TCP) such as ITO or IZO that can transmit light, or a semi-transmissive conductive material such as magnesium (Mg), silver (Ag) or an alloy of magnesium (Mg) and silver (Ag). When the cathode electrode 243 includes a translucent conductive material, the light emission efficiency may be increased through microcavities.

When the light-emitting element layer 204 is of a bottom-emission type in which light exits toward the lower side, the anode electrode 241 may include a transparent conductive material (TCP) such as ITO or IZO that can transmit light, or a semi-transmissive conductive material such as magnesium (Mg), silver (Ag) or an alloy of magnesium (Mg) and silver (Ag). The cathode electrode 243 may include a metal material having a high reflectivity such as a stack structure of aluminum and titanium (Ti/Al/Ti), a stack structure of aluminum and ITO (ITO/Al/ITO), an APC alloy or a stack structure of APC alloy and ITO (ITO/APC/ITO). When the anode electrode 241 includes a semi-transmissive conductive material, the light emission efficiency may be increased through microcavities.

The encapsulation layer 205 is disposed on the light-emitting element layer 204. The encapsulation layer 205 serves to prevent permeation of oxygen or moisture into the emissive layers 242 and the cathode electrode 243. To this end, the encapsulation layer 205 may include at least one inorganic film. The inorganic layer may include silicon nitride, aluminum nitride, zirconium nitride, titanium nitride, hafnium nitride, tantalum nitride, silicon oxide, aluminum oxide, or titanium oxide. Further, the encapsulation layer 205 may further include at least one organic film. The organic film may have a sufficient thickness to prevent particles from permeating into the encapsulation layer 205 and entering the emissive layer 242 and the cathode electrode 243. The organic layer may include one of epoxy, acrylate and urethane acrylate.

The sensor unit SENL may be disposed on the encapsulation layer 205. When the sensor unit SENL is disposed directly on the encapsulation layer 205, the thickness of the display device 10 may be reduced, compared to a display device in which a separate touch panel is attached on the encapsulation layer.

The sensor unit SENL may include sensor electrodes for sensing a user's touch using a capacitive method, and touch lines for connecting the pads with the sensor electrodes. For example, the sensor unit SENL can sense a user's touch through either a self-capacitance method or a mutual capacitance method. For example, as shown in FIG. 4, the sensor unit SENL may include two layers including driving electrodes TE, sensing electrodes RE and bridges BE connecting between the driving electrodes TE and detect a user's touch using a mutual capacitance method.

The bridges BE may be disposed on the encapsulation layer 205. The bridges BE may include, but is not limited to, a stack structure of aluminum and titanium (Ti/Al/Ti), a stack structure of aluminum and ITO (ITO/Al/ITO), an APC alloy or a stack structure of APC alloy and ITO (ITO/APC/ITO). For example, the bridges BE may include a single layer of molybdenum (Mo), titanium (Ti), copper (Cu), aluminum (Al) or ITO.

A first sensing insulating film TINS1 is disposed on the bridges BE. The first sensing insulating film TINS1 may include an inorganic film, for example, a silicon nitride layer, a silicon oxynitride layer, a silicon oxide layer, a titanium oxide layer, or an aluminum oxide layer.

The driving electrodes TE and the sensing electrodes RE may be disposed on the first sensing insulating film TINS1. The driving electrode TE and the sensing electrode RE may include, but is not limited to, a stack structure of aluminum and titanium (Ti/Al/Ti), a stack structure of aluminum and ITO (ITO/Al/ITO), an APC alloy or a stack structure of APC alloy and ITO (ITO/APC/ITO). For example, the driving electrodes TE and the sensing electrodes RE may include a single layer of molybdenum (Mo), titanium (Ti), copper (Cu), aluminum (Al) or ITO.

Contact holes may be formed in the first sensing insulating film TINS1 and extend to the bridges BE. The driving electrodes TE may be connected to the bridges BE through the contact holes.

A second sensing insulating film TINS2 is disposed on the driving electrodes TE and the sensing electrodes RE. The second sensing insulating film TINS2 may provide a flat surface over the driving electrodes TE, the sensing electrodes RE and the bridges BE which have different heights. The second sensing insulating film TINS2 may include an organic layer such as an acryl resin, an epoxy resin, a phenolic resin, a polyamide resin or a polyimide resin.

The bridges BE connecting two adjacent driving electrodes TE may be disposed on the encapsulation layer 205, and the driving electrodes TE and the sensing electrodes RE may be disposed on the first sensing insulating film TINS1. Therefore, the driving electrodes TE and the sensing electrodes RE may be electrically separated from each other at their intersections. That is to say, while the sensing electrodes RE may be electrically connected with one another in a first direction, the driving electrodes TE may be electrically connected with one another in a second direction, different from the first direction, through the bridge BE.

The polarizing film PF may be disposed on the second sensing insulating film TINS2 and prevent the deterioration of image visibility of the display panel 200 due to the reflection of external light.

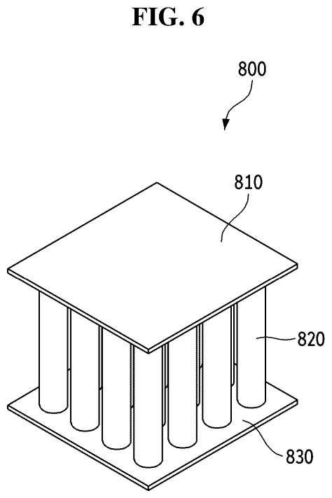

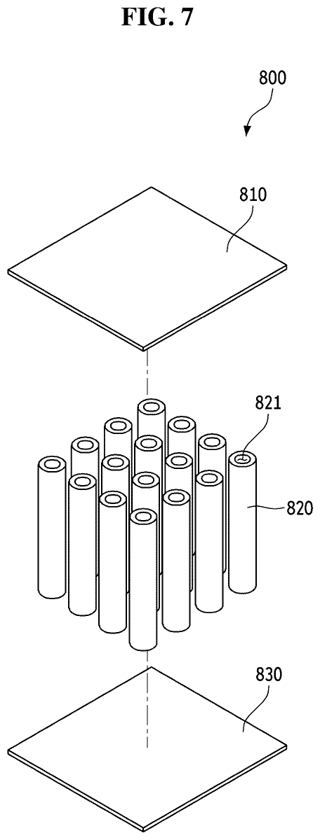

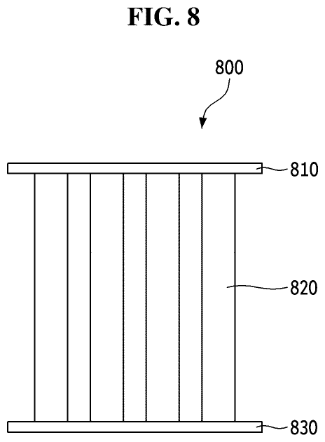

FIG. 6 is a perspective view showing a heat dissipation member shown in FIG. 4. FIG. 7 is an exploded perspective view of a heat dissipation member shown in FIG. 6. FIG. 8 is a side view of a heat dissipation member shown in FIG. 6.

Referring to FIGS. 6 and 8, the heat dissipation member 800 may include a top plate 810, heat dissipation fins 820, and a bottom plate 830.

The top plate 810 may be provided as a plate having a predetermined thickness. The shape of the top plate 810 may be formed in, but is not limited to, a rectangular shape when viewed from the top. The shape of the top plate 810 may also be formed in a polygonal shape other than a rectangular shape, a circular shape, or an elliptical shape when viewed from the top. The top plate 810 may include a metal material.

The heat dissipation fins 820 may extend downward from a lower surface of the top plate 810. The heat dissipation fins 820 may be formed in, but is not limited to, a cylindrical shape. The heat dissipation fins 820 may be formed in a triangular column shape, a rectangular column shape, or other polygonal column shapes, or may be formed in an elliptical column shape. The heat dissipation fins 820 may include the same metal material as the top plate 810.

Each of the heat dissipation fins 820 may be spaced apart from one another. The heat dissipation fins 820 may be arranged in rows and columns such that they are spaced apart from one another.

Heat dissipation holes 821 may be formed in the heat dissipation fins 820, respectively, which penetrate the heat dissipation fins 820. The shape of the heat dissipation holes 821 may be circular when viewed from the top, but the present disclosure is not limited thereto. The shape of the heat dissipation holes 821 may be formed in a triangular shape, a rectangular shape, or other polygonal shapes, or may be formed in an elliptical shape. A first side of the heat dissipation fins 820 may be in contact with the lower surface of the top plate 810, and a second side of the heat dissipation fins 820, which is opposite side to the first side of the heat dissipation fins 820, may be in contact with an upper surface of the bottom plate 830. The heat dissipation holes 821 may penetrate the heat dissipation fins 820 from the first side to the second side of the heat dissipation fins 820.

The bottom plate 830 may be provided as a plate having a predetermined thickness. The shape of the bottom plate 830 may be formed in, but is not limited to, a rectangular shape when viewed from the top. The shape of the bottom plate 830 may also be formed in a polygonal shape other than a rectangular shape, a circular shape, or an elliptical shape when viewed from the top. The bottom plate 830 may have a shape conforming to the top plate 810 when viewed from the top.

The top plate 810, the heat dissipation fins 820 and the bottom plate 830 may include the same metal material, for example, copper (Cu).

In the following description, the top plate 810 will be referred to as a first side of the heat dissipation member 800, while the bottom plate 830 will be referred to as a second side of the heat dissipation member 800 for convenience of explanation.

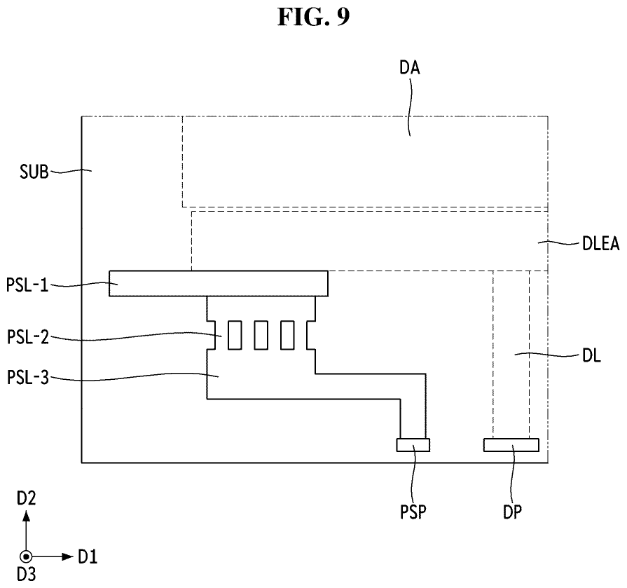

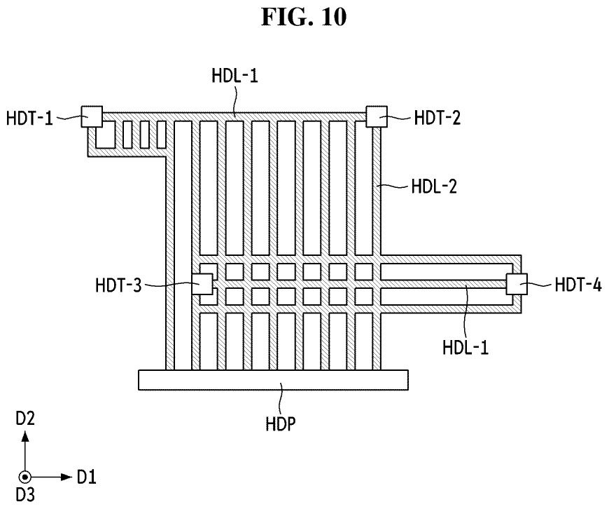

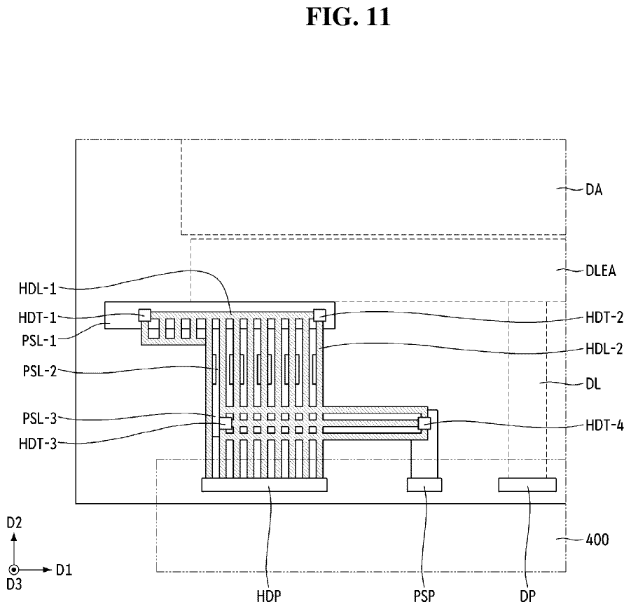

FIG. 9 is a plan view showing a part of a substrate shown in FIG. 4. FIG. 10 is a plan view showing a connected state of a plurality of heat dissipation terminals, a plurality of heat dissipation lines, and a plurality of heat dissipation pads arranged on a part of a substrate shown in FIG. 9. FIG. 11 is a plan view showing an arrangement of a plurality of heat dissipation terminals, a plurality of heat dissipation lines and a plurality of heat dissipation pads on a part of a substrate shown in FIG. 9.

Referring to FIGS. 9 to 11, the display panel 200 may further include a data pad DP, a data line DL, a data line extension DLEA, a power supply pad PSP, a power supply line PSL, a heat dissipation terminal HDT, a heat dissipation line HDL, and a heat dissipation pad HDP.

The data pad DP may be disposed at an edge of the substrate SUB on a surface of the substrate SUB. The data pad DP may be disposed in the non-display area NDA of the substrate SUB. The data pad DP may be connected to the driver circuit board 500 through the connecting member 400 so that a data signal may be input from the driver circuit board 500.

The data line DL may be disposed on the surface of the substrate SUB. A plurality of data lines DL may be disposed. The plurality of data lines DL may extend from the data pad DP toward the display area DA. The data lines DL may provide paths for transmitting data signals input through the data pad DP.

The data line extension DLEA may be disposed near the display area DA on the surface of the substrate SUB. In the data line extension DLEA, a plurality of data lines DL may be extended to connect to a plurality of light-emitting elements arranged in the display area DA, respectively.

The power supply pad PSP may be disposed at an edge of the substrate SUB on the surface of the substrate SUB. The power supply pad PSP may be disposed in the non-display area NDA of the substrate SUB. The power supply pad PSP may be connected to the driver circuit board 500 through the connecting member 400 so that power may be input from the driver circuit board 500.

The power supply line PSL may be disposed on the surface of the substrate SUB. The power supply line PSL may extend from the power supply pad PSP toward the display area DA. The power supply line may provide a path for transmitting power input through the power supply pad PSP. The power supply line PSL may be connected to the light-emitting elements to provide power to the light-emitting elements.

A plurality of power supply lines may be disposed. The power supply lines may include a first power supply line PSL-1, a second power supply line PSL-2, and a third power supply line PSL-3.

The first power supply line PSL-1 may be disposed adjacent to the display area DA. The first power supply line PSL-1 may extend in the first direction D1. According to an embodiment, the first power supply line PSL-1 extends in the first direction D1, but the present disclosure is not limited thereto. The first power supply line PSL-1 may extend in the first direction D1, and the extended end may be bent to further extend in the second direction D2. The first power supply line PSL-1, extended in the second direction D2, may surround the display area DA. The first power supply line PSL-1 may be connected to a plurality of light-emitting elements in the display area DA.

The second power supply line PSL-2 may extend in the second direction D2 from the first power supply line PSL-1. The second power supply line PSL-2 may be extended from the first power supply line PSL-1 toward the power supply pad PSP.

The third power supply line PSL-3 may be disposed adjacent to the power supply pad PSP. The third power supply line PSL-3 may extend in the first direction D1. The third power supply line PSL-3 may be connected to the extended end of the second power supply line PSL-2. The third power supply line PSL-3 may be bent at one side and extend in the second direction D2, and the end extended in the second direction D2 may be connected to the power supply pad PSP.

The heat dissipation terminal HDT may be arranged to overlap with the power supply line. The heat dissipation terminal HDT may be provided in a plural form. A plurality of heat dissipation terminals HDT may include a first heat dissipation terminal HDT-1, a second heat dissipation terminal HDT-2, a third heat dissipation terminal HDT-3, and a fourth heat dissipation terminal HDT-4.

The first heat dissipation terminal HDT-1 and the second heat dissipation terminal HDT-2 may be disposed on a surface of the first power supply line PSL-1 and may overlap with the first power supply line PSL-1. The first heat dissipation terminal HDT-1 and the second heat dissipation terminal HDT-2 may be disposed on an upper surface of the first power supply line PSL-1. The first heat dissipation terminal HDT-1 and the second heat dissipation terminal HDT-2 may be spaced apart from each other in the first direction and may be disposed on opposite sides of the first power supply line PSL-1, respectively. For example, the first heat dissipation terminal HDT-1 may be disposed on a left side of the upper surface of the first power supply line PSL-1, and the second heat dissipation terminal HDT-2 may be disposed on a right side of the upper surface of the first power supply line PSL-1.

The third heat dissipation terminal HDT-3 and the fourth heat dissipation terminal HDT-4 may be disposed on a surface of the third power supply line PSL-3 and may overlap with the third power supply line PSL-3. The third heat dissipation terminal HDT-3 and the fourth heat dissipation terminal HDT-4 may be disposed on an upper surface of the third power supply line PSL-3. The third heat dissipation terminal HDT-3 and the fourth heat dissipation terminal HDT-4 may be spaced apart from each other in the first direction and may be disposed on opposite sides of the third power supply line PSL-3, respectively. For example, the third heat dissipation terminal HDT-3 may be disposed on a left side of the upper surface of the third power supply line PSL-3, and the fourth heat dissipation terminal HDT-4 may be disposed on a right side of the upper surface of the third power supply line PSL-3.

The heat dissipation line HDL may connect the first heat dissipation terminal HDT-1, the second heat dissipation terminal HDT-2, the third heat dissipation terminal HDT-3 and the fourth heat dissipation terminal HDT-4 with the heat dissipation pad HDP. The heat dissipation line HDL may be provided in a plural form. A plurality of heat dissipation lines may include a first heat dissipation line HDL-1 and a second heat dissipation line HDL-2. The first heat dissipation line HDL-1 may extend in the first direction, and the second heat dissipation line HDL-2 may extend in the second direction.

The first heat dissipation line HDL-1 may be provided in a plural form. One first heat dissipation line HDL-1 may connect the first heat dissipation terminal HDT-1 with the second heat dissipation terminal HDT-2, and another first heat dissipation line HDL-1 may connect the third heat dissipation terminal HDT-3 with the fourth heat dissipation terminal HDT-4. One first heat dissipation line HDL-1, connecting the first heat dissipation terminal HDT-1 with the second heat dissipation terminal HDT-2, may overlap with the first power supply line PSL-1, and another first heat dissipation line HDL-1, connecting the third heat dissipation terminal HDT-3 with the fourth heat dissipation terminal HDT-4, may overlap with the third power supply line PSL-3.

A plurality of the second heat dissipation lines HDL-2 may extend in the second direction D2 perpendicular to the first direction D1, to connect a plurality of first heat dissipation lines HDL-1 with one another and to be connected to the heat dissipation pad HDP. Each of the plurality of the second heat dissipation lines HDL-2 may be spaced apart from one another in the first direction D1.

The heat dissipation pad HDP may be disposed at an edge of the substrate SUB on the surface of the substrate SUB. The heat dissipation pad HDP may be disposed in the non-display area NDA of the substrate SUB. The heat dissipation pad HDP may be connected to the first heat dissipation terminal HDT-1, the second heat dissipation terminal HDT-2, the third heat dissipation terminal HDT-3 and the fourth heat dissipation terminal HDT-4 through the plurality of the first heat dissipation lines HDL-1 and the plurality of the second heat dissipation lines HDL-2.

During the supply of the power to the light-emitting elements, heat may be generated along the power supply lines PSL-1 to PSL-3. The heat generated in the power supply lines PSL-1 to PSL-3 may be transferred to the first heat dissipation terminal HDT-1, the second heat dissipation terminal HDT-2, the third heat dissipation terminal HDT-3 and the fourth heat dissipation terminal HDT-4. The heat input through the first heat dissipation terminal HDT-1, the second heat dissipation terminal HDT-2, the third heat dissipation terminal HDT-3 and the fourth heat dissipation terminal HDT-4 may be delivered through the first heat dissipation lines HDL-1 and the second heat dissipation lines HDL-2 to the heat dissipation pad HDP. The heat thus transferred to the heat dissipation pad HDP may be dissipated to the outside of the display panel 200 through the connecting member 400.

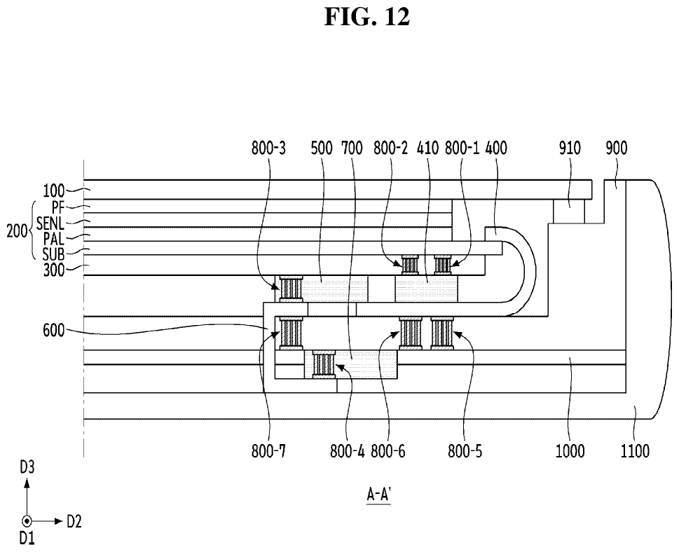

FIG. 12 is a cross-sectional view taken along a line A-A′ of FIG. 1.

Referring to FIG. 12, the electronic device 1 according to an embodiment of the present disclosure may further include a bracket 900, a vapor chamber 1000, and a back cover 1100.

The bracket 900 may support the display device 10. The bracket 900 may be disposed under the connecting member 400 and the driver circuit board 500. One end of the bracket 900 may protrude in the third direction D3 that is the thickness direction of the display device 10 and may be located under the cover window 100. An adhesive 910 may be disposed between the one end of the bracket 900 and the cover window 100 to fix the bracket 900 to the cover window 100. A control circuit board 700 may be disposed under the bracket 900 as the cable 600 is bent.

The vapor chamber 1000 may be disposed under the bracket 900. The vapor chamber 1000 may have a vacuum space formed inside, and a heat transfer medium may be accommodated in the internal vacuum space. The vapor chamber 1000 may dissipate heat generated in the display device 10 by a phase change of the heat transfer medium accommodated in the internal vacuum space.

The back cover 1100 may form a part of the exterior of the electronic device 1. The back cover 1100 may be formed to surround the internal elements of the electronic device 1 except the cover window 100. The back cover 1100 may be disposed at the bottom of the display device 10 to cover the internal electronic components of the display device 10, thereby protecting the display device 10 from external impact.

According to an embodiment, the electronic device 1 may include a plurality of heat dissipation members 800. The heat dissipation members 800 may include a first heat dissipation member 800-1, a second heat dissipation member 800-2, a third heat dissipation member 800-3, a fourth heat dissipation member 800-4, a fifth heat dissipation member 800-5, a sixth heat dissipation member 800-6, and a seventh heat dissipation member 800-7.

The first heat dissipation member 800-1 and the second heat dissipation member 800-2 may be disposed inside the panel bottom member 300. The first heat dissipation member 800-1 and the second heat dissipation member 800-2 may overlap with the driver integrated circuit 410. The first heat dissipation member 800-1 and the second heat dissipation member 800-2 may be disposed inside the panel bottom member 300 so that they are located on the driver integrated circuit 410.

An upper side of the first heat dissipation member 800-1 and an upper side of the second heat dissipation member 800-2 may be in contact with the lower surface of the substrate SUB of the display panel 200, and a lower side of the first heat dissipation member 800-1 and a lower side of the second heat dissipation member 800-2 may be in contact with the upper surface of the driver integrated circuit 410. In other words, the top plates of the first heat dissipation member 800-1 and the second heat dissipation member 800-2 may be in contact with the lower surface of the substrate SUB, and the bottom plates of the first heat dissipation member 800-1 and the second heat dissipation member 800-2 may be in contact with the upper surface of the driver integrated circuit 410. The first heat dissipation member 800-1 and the second heat dissipation member 800-2 may dissipate the heat generated in the substrate SUB toward the lower side of the substrate SUB. For example, the heat dissipation pad HDP formed on the surface of the substrate SUB may be connected to the top plate of the first heat dissipation member 800-1 or the top plate of the second heat dissipation member 800-2, and the heat, which is generated in the substrate SUB and transferred through the power supply lines PSL-1 to PSL-3, the heat dissipation terminals HDT-1 to HDT-4, the heat dissipation lines HDL-1 and HDL-2 to the heat dissipation pad HDP, may be dissipated outside through the first heat dissipation member 800-1 or the second heat dissipation member 800-2.

The third heat dissipation member 800-3 may be disposed inside the driver circuit board 500. The third heat dissipation member 800-3 may overlap with the cable 600. The third heat dissipation member 800-3 may be disposed inside the driver circuit board 500 so that it is located on the cable 600 connected to the driver circuit board 500.

An upper side of the third heat dissipation member 800-3 may be in contact with the lower surface of the panel bottom member 300, and a lower side of the third heat dissipation member 800-3 may be in contact with the upper surface of the cable 600 connected to the driver circuit board 500. In other words, the top plate of the third heat dissipation member 800-3 may be in contact with the lower surface of the panel bottom member 300, and the bottom plate of the third heat dissipation member 800-3 may be in contact with the upper surface of the cable 600 connected to the driver circuit board 500. The third heat dissipation member 800-3 may dissipate the heat generated in the driver circuit board 500 toward the lower side of the driver circuit board 500.

The fourth heat dissipation member 800-4 may be disposed inside the control circuit board 700. The fourth heat dissipation member 800-4 may overlap with the cable 600. The fourth heat dissipation member 800-4 may be disposed inside the control circuit board 700 so that it is located on the cable 600 connected to the control circuit board 700.

A lower side of the fourth heat dissipation member 800-4 may be in contact with the cable 600 connected to the control circuit board 700, and an upper side of the fourth heat dissipation member 800-4 may be in contact with the bracket 900. In other words, the bottom plate of the fourth heat dissipation member 800-4 may be in contact with the cable 600 connected to the control circuit board 700, and the top plate of the fourth heat dissipation member 800-4 may be in contact with the bracket 900. The fourth heat dissipation member 800-4 may dissipate the heat generated in the control circuit board 700 toward outside of the control circuit board 700.

The fifth heat dissipation member 800-5 and the sixth heat dissipation member 800-6 may be disposed inside the bracket 900. The fifth heat dissipation member 800-5 and the sixth heat dissipation member 800-6 may overlap with the driver integrated circuit 410. The fifth heat dissipation member 800-5 and the sixth heat dissipation member 800-6 may be disposed inside the bracket 900 so that they are located under the driver integrated circuit 410. In addition, the fifth heat dissipation member 800-5 may overlap with the first heat dissipation member 800-1, and the sixth heat dissipation member 800-6 may overlap with the second heat dissipation member 800-2.

An upper side of the fifth heat dissipation member 800-5 and an upper side of the sixth heat dissipation member 800-6 may be in contact with the lower surface of the connecting member 400, and a lower side of the fifth heat dissipation member 800-5 and a lower side of the sixth heat dissipation member 800-6 may be in contact with the upper surface of the vapor chamber 1000. In other words, the top plates of the fifth heat dissipation member 800-5 and the sixth heat dissipation member 800-6 may be in contact with the lower surface of the connecting member 400, and the bottom plates of the fifth heat dissipation member 800-5 and the sixth heat dissipation member 800-6 may be in contact with the upper surface of the vapor chamber 1000. The fifth heat dissipation member 800-5 and the sixth heat dissipation member 800-6 may further dissipate the heat discharged downward by the first heat dissipation member 800-1 and the second heat dissipation member 800-2 toward the lower side of the bracket 900.

The seventh heat dissipation member 800-7 may be disposed inside the bracket 900. The seventh heat dissipation member 800-7 may overlap with the driver circuit board 500. The seventh heat dissipation member 800-7 may be disposed inside the bracket 900 so that it is located under the driver circuit board 500. In addition, the seventh heat dissipation member 800-7 may overlap with the third heat dissipation member 800-3.

An upper side of the seventh heat dissipation member 800-7 may be in contact with the cable 600 connected to the driver circuit board 500, and a lower side of the seventh heat dissipation member 800-7 may be in contact with the upper surface of the vapor chamber 1000. In other words, the top plate of the seventh heat dissipation member 800-7 may be in contact with the cable 600 connected to the driver circuit board 500, and the bottom plate of the seventh heat dissipation member 800-7 may be in contact with the upper surface of the vapor chamber 1000. The seventh heat dissipation member 800-7 may further dissipate the heat discharged downward by the third heat dissipation member 800-3 toward the lower side of the bracket 900.

The foregoing is illustrative of the inventive concept of the present disclosure and is not to be construed as limiting thereof. Although several embodiments of the present disclosure have been described, those skilled in the art will readily appreciate that many modifications are possible without materially departing from the novel teachings and advantages of the present disclosure. Accordingly, it will be understood that all such modifications are intended to be included within the scope of the present disclosure as defined in the claims. It will be understood that the scope of the present disclosure is defined by the following claims, with equivalents of the claims to be included therein.

What is claimed is:

1. A display device comprising:
a display panel;
a panel bottom member disposed under the display panel;
a driver circuit board connected to the display panel;
a control circuit board connected to the driver circuit board; and
a heat dissipation member disposed in at least one of the panel bottom member, the driver circuit board, or the control circuit board.

2. The display device of claim 1, further comprising:
a driver integrated circuit disposed under the panel bottom member,
wherein the heat dissipation member is disposed in the panel bottom member and overlaps with the driver integrated circuit.

3. The display device of claim 2, wherein a top plate of the heat dissipation member is in contact with the display panel, and a bottom plate of the heat dissipation member is in contact with the driver integrated circuit.

4. The display device of claim 1, further comprising:
a cable connecting the driver circuit board with the control circuit board,
wherein the heat dissipation member is disposed in the driver circuit board and overlaps with the cable.

5. The display device of claim 4, wherein a top plate of the heat dissipation member is in contact with the panel bottom member, and a bottom plate of the heat dissipation member is in contact with the cable.

6. The display device of claim 1, further comprising:
a cable connecting the driver circuit board with the control circuit board,
wherein the heat dissipation member is disposed in the control circuit board and overlaps with the cable.

7. The display device of claim 6, wherein a top plate of the heat dissipation member is in contact with the cable.

8. The display device of claim 1, wherein the heat dissipation member comprises:
a top plate;
a bottom plate spaced apart from the top plate; and
a plurality of heat dissipation fins connecting the top plate with the bottom plate.

9. The display device of claim 8, wherein a first side of each of the plurality of heat dissipation fins is in contact with the top plate, and a second side of each of the plurality of heat dissipation fins is in contact with the bottom plate, and
wherein each of the plurality of heat dissipation fins includes a heat dissipation hole that extends through each of the plurality of heat dissipation fins from the first side to the second side.

10. The display device of claim 1, wherein the display panel comprises:
a substrate; and
a plurality of light-emitting elements disposed on a surface of the substrate,
wherein the substrate includes:
a power supply line supplying power to the plurality of light-emitting elements;
a plurality of heat dissipation terminals overlapping the power supply line;
a plurality of heat dissipation lines connecting each of the plurality of heat dissipation terminals; and
a heat dissipation pad disposed on the surface of the substrate and connected to the plurality of heat dissipation lines.

11. The display device of claim 10, wherein the power supply line extends from an area adjacent to the plurality of light-emitting elements to an area adjacent to the heat dissipation pad,
wherein the plurality of heat dissipation terminals comprises a first heat dissipation terminal, a second heat dissipation terminal, a third heat dissipation terminal and a fourth heat dissipation terminal,
wherein the first heat dissipation terminal and the second heat dissipation terminal are spaced apart from each other in a first direction and overlap with the power supply line disposed in the area adjacent to the light-emitting element, and
wherein the third heat dissipation terminal and the fourth heat dissipation terminal are spaced apart from each other in the first direction and overlap with the power supply line disposed in the area adjacent to the heat dissipation pad.

12. The display device of claim 11, wherein the plurality of heat dissipation lines comprises a first heat dissipation line and a second heat dissipation line,
wherein the first heat dissipation line extending in the first direction connects the first heat dissipation terminal with the second heat dissipation terminal, and connects the third heat dissipation terminal with the fourth heat dissipation terminal, and
wherein the second heat dissipation line extending in a second direction intersecting the first direction connects the first heat dissipation line with the heat dissipation pad.

13. An electronic device comprising:
a display panel;
a panel bottom member disposed under the display panel;
a driver circuit board connected to the display panel;
a bracket disposed under of the driver circuit board;
a control circuit board connected to the driver circuit board and disposed under the bracket; and
a plurality of heat dissipation members disposed in at least one of the panel bottom member, the driver circuit board, the bracket, or the control circuit board.

14. The electronic device of claim 13, further comprising:
a driver integrated circuit disposed under the panel bottom member,
wherein the plurality of heat dissipation members comprises a first heat dissipation member and a second heat dissipation member, and
wherein the first heat dissipation member and the second heat dissipation member are disposed in the panel bottom member and overlap with the driver integrated circuit.

15. The electronic device of claim 14, wherein a top plate of each of the first heat dissipation member and the second heat dissipation member is in contact with the display panel, and a bottom plate of each of the first heat dissipation member and the second heat dissipation member is in contact with the driver integrated circuit.

16. The electronic device of claim 13, further comprising:
a cable connecting the driver circuit board with the control circuit board,
wherein the plurality of heat dissipation members comprises a third heat dissipation member and a fourth heat dissipation member,
wherein the third heat dissipation member is disposed in the driver circuit board and overlaps with the cable, and
wherein the fourth heat dissipation member is disposed in the control circuit board and overlaps with the cable.

17. The electronic device of claim 16, wherein a top plate of the third heat dissipation member is in contact with the panel bottom member, and a bottom plate of the third heat dissipation member is in contact with the cable, and
wherein a bottom plate of the fourth heat dissipation member is in contact with the cable, and a top plate of the fourth heat dissipation member is in contact with the bracket.

18. The electronic device of claim 14, wherein the plurality of heat dissipation members further comprises a fifth heat dissipation member and a sixth heat dissipation member,
wherein the fifth heat dissipation member is disposed in the bracket and overlaps with the first heat dissipation member, and
wherein the sixth heat dissipation member is disposed in the bracket and overlaps with the second heat dissipation member.

19. The electronic device of claim 18, wherein the plurality of heat dissipation members further comprises a seventh heat dissipation member, and
wherein the seventh heat dissipation member is disposed in the bracket and overlaps with the driver circuit board.

20. The electronic device of claim 19, further comprising:
a connecting member connecting the display panel with the driver circuit board;
a cable connecting the driver circuit board with the control circuit board; and
a vapor chamber disposed under the bracket,
wherein a top plate of each of the fifth heat dissipation member and the sixth heat dissipation member is in contact with the connecting member,
wherein a bottom plate of each of the fifth heat dissipation member and the sixth heat dissipation member is in contact with the vapor chamber,
wherein a top plate of the seventh heat dissipation member is in contact with the cable, and
wherein a bottom of the seventh heat dissipation member is in contact with the vapor chamber.
